(19) United States
(12) Patent Application Publication
(10) Pub. No.: US 2009/0146131 A1
(43) Pub. Date: Jun. 11, 2009

(54) Integrated Circuit, and Method for Manufacturing an Integrated Circuit

(76) Inventor: Thomas Happ, Dresden (DE)

Correspondence Address: SLATER & MATSIL, L.L.P., 17950 PRESTON ROAD, SUITE 1000, DALLAS, TX, 75252, US

(21) Appl. No.: 11/951,132

(22) Filed: Dec. 5, 2007

(51) Int. Cl. H01L 45/00

(52) U.S. Cl. 257/5; 438/102; 257/E45.002

(57) ABSTRACT

According to one embodiment of the present invention, a method of manufacturing an integrated circuit including a plurality of memory cells is provided, including: forming a first isolation layer including a plurality of contact elements, each contact element extending from the top surface of the first isolation layer to the bottom surface of the first isolation layer; forming a second isolation layer on the first isolation layer, wherein the material of the first isolation layer is different from the material of the second isolation layer; forming trenches within the second isolation layer above the contact elements, wherein the trenches are formed using an etching substance which selectively etches the material of the second isolation layer over the material of the first isolation layer; and filling the trenches with resistivity changing material.

### BACKGROUND

Semiconductors are used in integrated circuits for electronic applications, including radios, televisions, cell phones, and personal computing devices, as examples. One type of semiconductor device is a semiconductor storage device, such as a dynamic random access memory (DRAM) or a flash memory, both of which use charge to store information.

Magnetoresistive random access memory (MRAM) is a memory technology that may replace dynamic random access memory (DRAM) as the standard memory for computing devices. Non-volatile MRAMs allow for “instant on” systems, i.e., systems that come to life as soon as the computer system is turned on.

An MRAM cell includes a structure having ferromagnetic layers separated by a non-magnetic tunneling barrier layer that are arranged into a magnetic tunneling junction (MTJ). Digital information is stored and represented as specific orientations of magnetic moment vectors in the ferromagnetic layers. More particularly, the magnetization of one ferromagnetic layer (reference layer) is magnetically fixed or pinned, while the magnetization of the other ferromagnetic layer (free layer) can be switched between two preferred directions in the magnetization easy axis. The magnetization easy axis is typically selected to be in parallel alignment with the fixed magnetization of the ferromagnetic reference layer. Relative orientations of the free layer magnetization are also known as “parallel” and “antiparallel” states, respectively, which exhibit two different resistance values in response to a voltage applied across the magnetic tunneling junction (MTJ) barrier layer. Hence, the resistance of the MTJ reflects a specific state, which is decreased when the magnetization is parallel and increased when the magnetization is antiparallel. Detection of resistivity allows an MRAM cell to provide logic information assigned to the two different resistivity states.

Memory circuits having memory cells based on a solid electrolyte material are generally known as PMC (programmable metallization cell) or CBRAM (Conductive Bridging Random Access Memory). A PMC component used therefore has a solid electrolyte into which, depending on an electric field to be applied during writing, a low-resistance conductive path is formed or cancelled. As a result, a state of the PMC component can be set by setting a high-resistance or low-resistance state. The two resistance values can respectively be assigned a logic state, and a PMC memory circuit can thus be formed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic drawing of an integrated circuit having phase change memory cells;

FIG. 1B shows a perspective view of an integrated circuit having magneto-resistive memory cells;

FIG. 2 shows a schematic drawing of a circuit usable in conjunction with the integrated circuit shown in FIG. 1;

FIG. 3A shows a schematic cross-sectional view of a programmable metallization cell set to a first switching state;

FIG. 3B shows a schematic cross-sectional view of a programmable metallization cell set to a second switching state;

FIG. 4 shows a schematic cross-sectional view of a phase change memory cell;

FIG. 5 shows a schematic drawing of an integrated circuit including resistivity changing memory cells;

FIG. 6A shows a schematic cross-sectional view of a carbon memory cell set to a first switching state;

FIG. 6B shows a schematic cross-sectional view of a carbon memory cell set to a second switching state;

FIG. 7A shows a schematic drawing of an integrated circuit including resistivity changing memory cells;

FIG. 7B shows a schematic drawing of an integrated circuit including resistivity changing memory cells;

FIG. 8 shows a flowchart of a method of manufacturing an integrated circuit according to one embodiment of the present invention;

FIG. 9 shows a flowchart of a method of manufacturing an integrated circuit according to one embodiment of the present invention;

FIG. 10 shows a schematic cross-sectional view of a phase change memory cell;

FIG. 11 shows a schematic cross-sectional view of a manufacturing stage of a method of manufacturing an integrated circuit according to one embodiment of the present invention;

FIG. 12 shows a schematic cross-sectional view of a manufacturing stage of a method of manufacturing an integrated circuit according to one embodiment of the present invention;

FIG. 13 shows a schematic cross-sectional view of a manufacturing stage of a method of manufacturing an integrated circuit according to one embodiment of the present invention;

FIG. 14 shows a schematic cross-sectional view of a manufacturing stage of a method of manufacturing an integrated circuit according to one embodiment of the present invention;

FIG. 15 shows a schematic cross-sectional view of a manufacturing stage of a method of manufacturing an integrated circuit according to one embodiment of the present invention;

FIG. 16 shows a schematic cross-sectional view of a manufacturing stage of a method of manufacturing an integrated circuit according to one embodiment of the present invention;

FIG. 17 shows a schematic cross-sectional view of a manufacturing stage of a method of manufacturing an integrated circuit according to one embodiment of the present invention;

FIG. 18 shows a schematic cross-sectional view of a manufacturing stage of a method of manufacturing an integrated circuit according to one embodiment of the present invention;

FIG. 19 shows a schematic cross-sectional view of a manufacturing stage of a method of manufacturing an integrated circuit according to one embodiment of the present invention;

FIG. 20A shows a schematic perspective view of a memory module according to one embodiment of the present invention; and

FIG. 20B shows a schematic perspective view of a memory module according to one embodiment of the present invention.

### DETAILED DESCRIPTION OF ILLUSTRATIVE EMBODIMENTS

According to one embodiment of the present invention, a method of manufacturing an integrated circuit including a plurality of memory cells is provided, including: forming a first isolation layer including a plurality of contact elements, each contact element extending from the top surface of the first isolation layer to the bottom surface of the first isolation layer; forming a second isolation layer on the first isolation layer, wherein the material of the first isolation layer is different from the material of the second isolation layer; forming trenches within the second isolation layer above the contact elements, wherein the trenches are formed using an etching substance which selectively etches the material of the second isolation layer over the material of the first isolation layer; and filling the trenches with resistivity changing material.

According to one embodiment of the present invention, the first isolation layer is a nitride layer, and the second isolation layer is an oxide layer. According to one embodiment of the present invention, the first isolation layer is a silicon nitride layer, and the second isolation layer is a silicon oxide layer. However, the present invention is not restricted to these materials. Alternative materials are for example Al₂O₃, SiON, FSG (fluorosilicate glass), BSG (borosilicate glass), BPSG (borophosphosilicate glass), spin-on glasses (SOG), SiCOH, or other low-k dielectrics. According to one embodiment of the present invention, sidewall spacers are formed within the trenches before filling the trenches with resistivity changing material.

According to one embodiment of the present invention, the sidewall spacers are formed using a nitridation of the sidewalls of the trenches (e.g., an oxide nitridation assuming that the second isolation layer is an oxide layer). Alternatively, a spacer layer may be deposited, followed by a spacer layer etching process.

According to one embodiment of the present invention, the widths of the trenches and of the sidewall spacers are chosen such that the distance between two neighboring sidewall spacers is lower than 1F, F being the minimum litography feature width.

According to one embodiment of the present invention, the width of each trench is about 1F.

One effect of chosing such dimensions is that structures lower that 1F can be manufactured using masks having patterns not lower than 1F.

According to one embodiment of the present invention, the memory cell is a phase change memory cell, and the resistivity changing material is phase change material. However, the present invention is also applicable to other types of resistivity changing memory devices like magneto-resistive memory devices (e.g., MRAM devices, programmable metallization devices (e.g., CBRAM devices), transistion metal oxide (TMO) devices, and the like.

According to one embodiment of the present invention, a top electrode layer is formed on the second isolation layer, and a bit line layer is formed on the top electrode layer.

According to one embodiment of the present invention, the bit line layer is patterned into bit lines by forming trenches within the bit line layer.

According to one embodiment of the present invention, the formation of the trenches within the bit line layer is carried out using the top electrode layer as an etch stop layer.

According to one embodiment of the present invention, the top electrode layer is patterned using the patterned bit line layer as an electrode layer patterning mask.

According to one embodiment of the present invention, an encapsulation layer is deposited on at least a part of the surface of the bit lines.

According to one embodiment of the present invention, the material of the encapsulation layer is the same material as that of the first isolation layer, e.g., silicon nitride.

According to one embodiment of the present invention, the patterning of the top electrode layer is carried out after having formed the encapsulation layer, wherein the parts of the encapsulation layer covering the sidewalls of the bit lines are used as part of the electrode layer patterning mask when patterning the top electrode layer.

More generally, according to one embodiment of the present invention, a method of manufacturing an integrated circuit comprising a plurality of memory cells is provided, comprising: forming a first isolation layer comprising a plurality of resistivity changing memory elements, each resistivity changing memory element extending from the top surface of the first isolation layer into the first isolation layer; forming a top electrode layer on the first isolation layer; forming a pattern of bit lines on the top electrode layer; and patterning the top electrode layer using the bit line pattern as a top electrode layer patterning mask, wherein the patterning of the top electrode layer is carried out after having formed an encapsulation layer on at least a part of the surface of the bit lines, wherein the parts of the encapsulation layer covering the sidewalls of the bit lines are used as a part of the top electrode layer patterning mask when patterning the top electrode layer. This embodiment can be applied to arbitrary types of memory devices.

According to one embodiment of the present invention, an etch stop layer is formed on the second isolation layer. Then, a third isolation layer is formed on the etch stop layer. Trenches are formed within the third isolation layer extending to the top surface of the etch stop layer using a first etching substance, each trench being formed above a trench filled with resistivity changing material. Then, the parts of the etch stop layer are opened which are positioned above the trenches filled with resistivity changing material using a second etching substance. Last, the trenches thus obtained are filled with bit line material.

According to one embodiment of the present invention, the widths of the trenches between the bit lines and the thicknesses of the sidewall spacers covering the sidewalls of the bit lines are chosen such that the distance between two neighboring sidewall spacers is lower than about 1F.

According to one embodiment of the present invention, the width of each trench between two neighboring bit lines is about 1F.

One effect of choosing such dimensions is that structures lower that about 1F can be a relaxation of the overlay accuracy requirements between the trenches within the second isolation layer and the trenches between the bit lines.

All embodiments discussed above may also be applied, if applicable, to the following embodiment.

According to one embodiment of the present invention, a method of manufacturing an integrated circuit including a plurality of memory cells is provided, including: forming a contact element arrangement; forming a first isolation layer including a plurality of first trenches on the contact element arrangement, each first trench extending from the top surface of the first isolation layer to the bottom surface of the first isolation layer and being arranged above a contact element; forming a second isolation layer on the first isolation layer, wherein the material of the first isolation layer is different from the material of the second isolation layer; forming second trenches within the second isolation layer, wherein each second trench is arranged above a first trench, wherein the second trenches are formed using an etching substance which selectively etches the material of the second isolation layer over the material of the first isolation layer; and filling the first trenches and second trenches with resistivity changing material.

According to one embodiment of the present invention, the second trenches are wider than the first trenches.

According to one embodiment of the present invention, before filling the first trenches and the second trenches with resistivity changing material, the sidewalls of the second trenches are covered with a sidewall spacer.

According to one embodiment of the present invention, the sidewall spacers are formed using a nitridation of the sidewalls of the trenches (e.g., an oxide nitridation assuming that the second isolation layer is an oxide layer). Alternatively, a spacer layer may be deposited, followed by a spacer layer etching process.

According to one embodiment of the present invention, a method of manufacturing a memory cell is provided, including: forming a first isolation layer including a contact element extending through the first isolation layer; forming a second isolation layer on the first isolation layer, wherein the material of the first isolation layer is different from the material of the second isolation layer; forming a trench within the second isolation layer above the contact element, wherein the trench is formed using an etching substance which selectively etches the material of the first isolation layer over the material of the second isolation layer; and filling the trench with resistivity changing material.

According to one embodiment of the present invention, a method of manufacturing a memory cell is provided, including: forming a contact element; forming a first isolation layer including a first trench on the contact element, the first trench extending from the top surface of the first isolation layer to the bottom surface of the first isolation layer and being arranged above the contact element; forming a second isolation layer on the first isolation layer, wherein the material of the first isolation layer is different from the material of the second isolation layer; forming a second trench within the second isolation layer, wherein the second trench is arranged above the first trench, wherein the second trench is formed using an etching substance which selectively etches the material of the second isolation layer over the material of the first isolation layer; and filling the first trench and second trench with resistivity changing material.

According to one embodiment of the present invention, an integrated circuit including a plurality of memory cells is provided, each memory cell including: a first isolation layer including a contact element which extends from the top surface of the first isolation layer to the bottom surface of the first isolation layer; a second isolation layer provided on the first isolation layer, wherein the second isolation layer includes a resistivity changing element which extends from the top surface of the second isolation layer to the bottom surface of the second isolation layer and which is arranged above the contact element, and wherein the material of the first isolation layer is different from the material of the second isolation layer.

According to one embodiment of the present invention, the first isolation layer is a nitride layer, and the second isolation layer is an oxide layer.

According to one embodiment of the present invention, the first isolation layer is a silicon nitride layer, and the second isolation layer is a silicon oxide layer.

According to one embodiment of the present invention, the sidewalls of the resistivity changing element are covered with sidewall spacers.

According to one embodiment of the present invention, the distance between two neighboring sidewall spacers belonging to neighboring memory cells is lower than about 1F.

According to one embodiment of the present invention, the distance between two neighboring resistivity changing elements is about 1F.

According to one embodiment of the present invention, the memory cell is a phase change memory cell, and the resistivity changing material is phase change material.

According to one embodiment of the present invention, each memory cell further includes a top electrode layer being provided on the second isolation layer, and a bit line layer being provided on the electrode layer.

According to one embodiment of the present invention, the material of the bit line layer and the material of the top electrode layer are chosen such that the material of the bit line layer can be selectively etched over the material of the top electrode layer.

According to one embodiment of the present invention, the sidewalls of the bit line layer are covered by sidewall spacers.

According to one embodiment of the present invention, the bit line is covered by an encapsulation layer.

According to one embodiment of the present invention, the parts of the encapsulation layer covering the sidewalls of the bit line function as sidewall spacers.

According to one embodiment of the present invention, the distance between two neighboring sidewall spacers belonging to neighboring memory cells is lower than about 1F.

According to one embodiment of the present invention, the distance between neighboring bit lines is about 1F.

All embodiments (concerning the integrated circuit) discussed above can also be applied, if applicable, to the following embodiment.

According to one embodiment of the present invention, an integrated circuit including a plurality of memory cells is provided, each memory cell including: a contact element; a first isolation layer which is provided on the contact element and which includes a first trench extending from the top surface of the first isolation layer to the bottom surface of the first isolation layer, wherein the first trench is arranged above the contact element; a second isolation layer provided on the first isolation layer, wherein the second isolation layer includes a second trench arranged above the first trench, wherein the second trench is wider than the first trench, and wherein the second trench extends from the top surface of the second isolation layer to the bottom surface of the second isolation layer, wherein the material of the first isolation layer is different from the material of the second isolation layer, and wherein the first trench and the second trench are filled with resistivity changing material.

According to one embodiment of the present invention, a memory module including at least one integrated circuit as described above is provided. According to one embodiment of the present invention, the memory module is stackable.

Since the embodiments of the present invention can be applied to phase changing memory devices which include resistivity changing memory cells (phase change memory cells), a brief discussion of phase changing memory devices will be given.

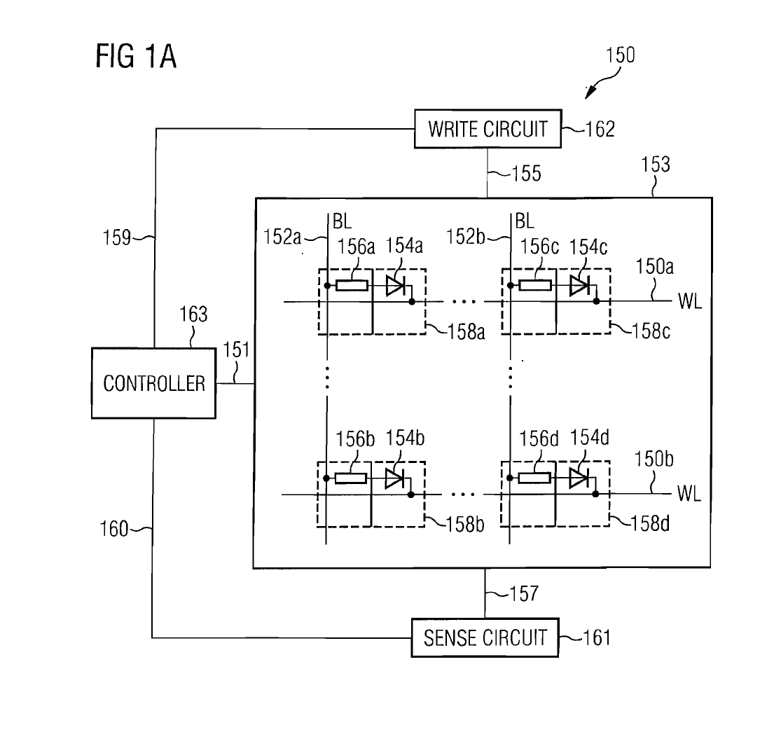

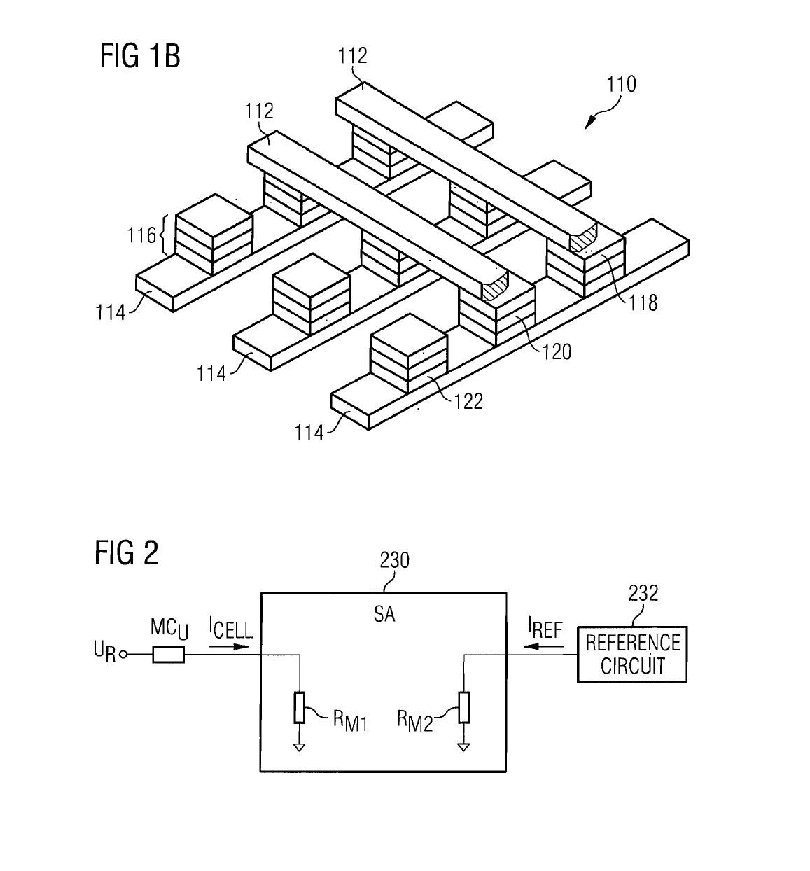

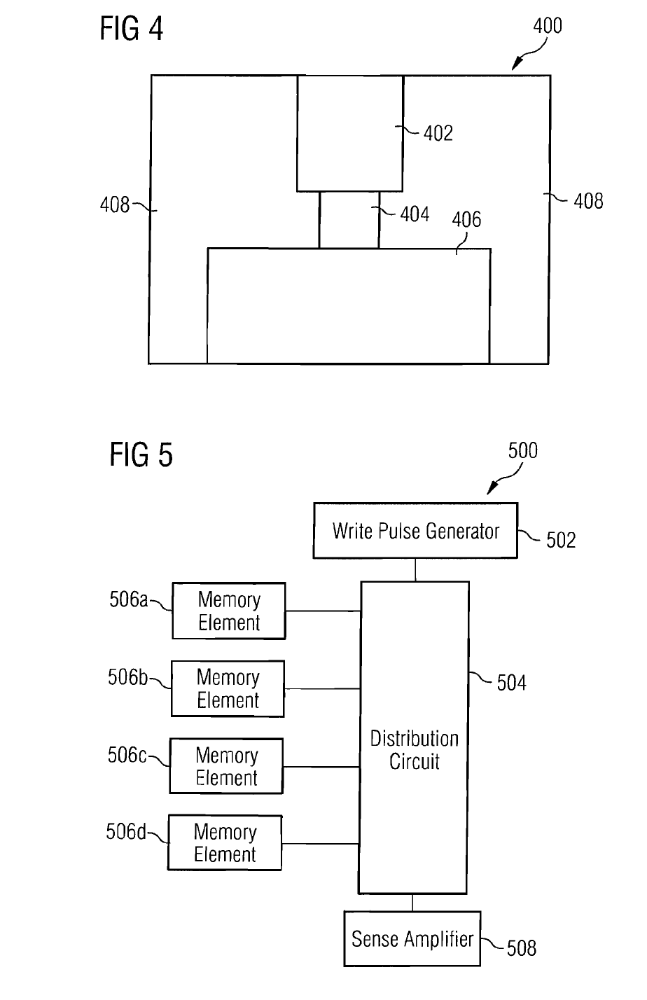

FIG. 1A shows a PCRAM-device 150 having a cell field 153, a writing ciruit 162, a sensing circuit 161, a controller 163, and bit lines 152a, 152b being arranged perpendicular to the word lines 150a, 150b. PCRAM elements (phase changing elements) 156a-156d are arranged between the bit lines 152a, 152b and the word lines 150a, 150b and are electrically coupled with the the bit lines 152a, 152b and the word lines 150a, 150b. Between the PCRAM elements 156a-156d and the word lines 150a, 150b, select devices (here: diodes which may be replaced by field effect transistors or by bipolar transistors) 154a-154d are arranged, thus forming PCRAM memory cells 158a-158d. The controller 163 controls the sensing circuit 161 and the writing circuit 162 connected to the controller 163 via lines 159, 160. The writing circuit 162 sets the memory states of the memory cells 158a-158d via lines 155, and the reading circuit reads the memory states of the memory cells 158a-158d via lines 157. More details about PCRAM-devices will be given later in conjunction with FIGS. 4 and 5.

Since the embodiments of the present invention can be applied to magneto-resistive memory devices which include resistivity changing memory cells (magneto-resistive memory cells), a brief discussion of magneto-resistive memory devices will be given. Magneto-resistive memory cells involve spin electronics, which combines semiconductor technology and magnetics. The spin of an electron, rather than the charge, is used to indicate the presence of a “1” or “0”. One such spin electronic device is a magnetic random-access memory (MRAM), which includes conductive lines positioned perpendicular to one another in different metal layers, the conductive lines sandwiching a magnetic stack. The place where the conductive lines intersect is called a cross-point. A current flowing through one of the conductive lines generates a magnetic field around the conductive line and orients the magnetic polarity into a certain direction along the wire or conductive line. A current flowing through the other conductive line induces the magnetic field and can also partially turn the magnetic polarity. Digital information, represented as a “0” or “1” is stored in the alignment of magnetic moments. The resistance of the magnetic component depends on the moment's alignment. The stored state is read from the element by detecting the component's resistive state. A memory cell may be constructed by placing the conductive lines and cross-points in a matrix structure or array having rows and columns.

FIG. 1B illustrates a perspective view of a MRAM device 110 having bit lines 112 located orthogonal to word lines 114 in adjacent metallization layers. Magnetic stacks 116 are positioned between the bit lines 112 and word lines 114 adjacent and electrically coupled to bit lines 112 and word lines 114. Magnetic stacks 116 preferably include multiple layers, including a soft layer 118, a tunnel layer 120, and a hard layer 122, for example. Soft layer 118 and hard layer 122 preferably include a plurality of magnetic metal layers, for example, eight to twelve layers of materials such as PtMn, CoFe, Ru, and NiFe, as examples. A logic state is storable in the soft layer 118 of the magnetic stacks 116 located at the junction of the bitlines 112 and word lines 114 by running a current in the appropriate direction within the bit lines 112 and word lines 114 which changes the resistance of the magnetic stacks 116.

In order to read the logic state stored in the soft layer 118 of the magnetic stack 116, a schematic such as the one shown in FIG. 2, including a sense amplifier (SA) 230, is used to determine the logic state stored in an unknown memory cell MCu. A reference voltage U_{R} is applied to one end of the unknown memory cell MCu. The other end of the unknown memory cell MCu is coupled to a measurement resistor Rₘ₁. The other end of the measurement resistor Rₘ₁ is coupled to ground. The current running through the unknown memory cell MCu is equal to current I_{cell}. A reference circuit 232 supplies a reference current I_{ref} that is run into measurement resistor Rₘ₂. The other end of the measurement resistor Rₘ₂ is coupled to ground, as shown.

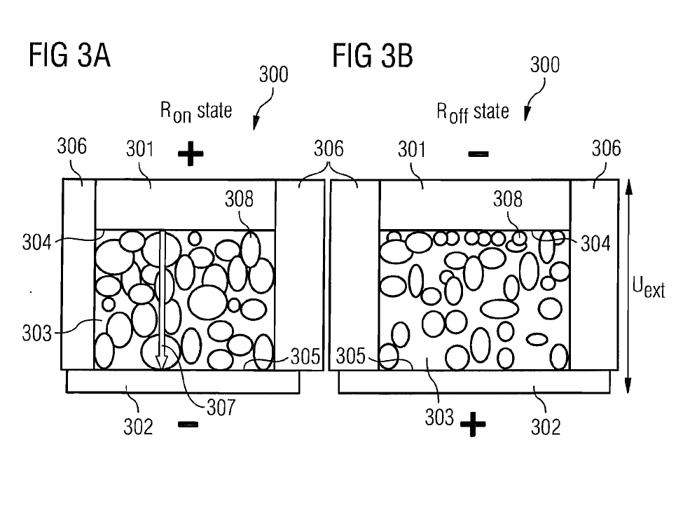

Since the embodiments of the present invention can be applied to programmable metallization cell devices (PMC) (e.g., solid electrolyte devices like CBRAM (conductive bridging random access memory) devices), in the following description, making reference to FIGS. 3A and 3B, a basic principle underlying embodiments of CBRAM devices will be explained.

As shown in FIG. 3A, a CBRAM element 300 includes a first electrode 301 a second electrode 302, and a solid electrolyte block (in the following also referred to as ion conductor block) 303 which includes the active material and which is sandwiched between the first electrode 301 and the second electrode 302. This solid electrolyte block 303 can also be shared between a plurality of memory elements (not shown here). The first electrode 301 contacts a first surface 304 of the ion conductor block 303, the second electrode 302 contacts a second surface 305 of the ion conductor block 303. The ion conductor block 303 is isolated against its environment by an isolation structure 306. The first surface 304 usually is the top surface, the second surface 305 the bottom surface of the ion conductor 303. In the same way, the first electrode 301 generally is the top electrode, and the second electrode 302 the bottom electrode of the CBRAM element. One of the first electrode 301 and the second electrode 302 is a reactive electrode, the other one an inert electrode. Here, the first electrode 301 is the reactive electrode, and the second electrode 302 is the inert electrode. In this example, the first electrode 301 includes silver (Ag), the ion conductor block 303 includes silver-doped chalcogenide material, the second electrode 302 includes tungsten (W), and the isolation structure 306 includes SiO₂ or Si₃N₄. The present invention is however not restricted to these materials. For example, the first electrode 301 may alternatively or additionally include copper (Cu) or zinc (Zn), and the ion conductor block 303 may alternatively or additionally include copper-doped chalcogenide material. Further, the second electrode 302 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 303 may, for example, range between about 5 nm and about 500 nm. The thickness of the first electrode 301 may, for example, range between about 10 nm and about 100 nm. The thickness of the second electrode 302 may, for example, range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 3A is applied across the ion conductor block 303, a redox reaction is initiated which drives Ag⁺ ions out of the first electrode 301 into the ion conductor block 303 where they are reduced to Ag, thereby forming Ag rich clusters 308 within the ion conductor block 303. If the voltage applied across the ion conductor block 303 is applied for an enhanced period of time, the size and the number of Ag rich clusters within the ion conductor block 303 is increased to such an extent that a conductive bridge 307 between the first electrode 301 and the second electrode 302 is formed. In case that a voltage is applied across the ion conductor 303 as shown in FIG. 3B (inverse voltage compared to the voltage applied in FIG. 3A), a redox reaction is initiated which drives Ag⁺ ions out of the ion conductor block 303 into the first electrode 301 where they are reduced to Ag. As a consequence, the size and the number of Ag rich clusters within the ion conductor block 303 is reduced, thereby erasing the conductive bridge 307. After having applied the voltage/inverse voltage, the memory element 300 remains within the corresponding defined switching state even if the voltage/inverse voltage has been removed.

In order to determine the current memory status of a CBRAM element, for example, a sensing current is routed through the CBRAM element. The sensing current experiences a high resistance in case no conductive bridge 307 exists within the CBRAM element, and experiences a low resistance in case a conductive bridge 307 exists within the CBRAM element. A high resistance may for example represent “0”, whereas a low resistance represents “1”, or vice versa. The memory status detection may also be carried out using sensing voltages. Alternatively, a sensing voltage may be used in order to determine the current memory status of a CBRAM element.

Since the embodiments of the present invention can be applied to phase change memory devices, in the following description, a basic principle underlying embodiments of PCRAM devices will be explained.

According to one embodiment of the invention, the resistivity changing memory elements are phase change memory elements that include a phase change material. The phase change material can be switched between at least two different crystallization states (i.e., the phase change material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase change material can adopt two crystallization states (an “amorphous state” and a “crystalline state”), however it will be understood that additional intermediate states may also be used.

Phase change memory elements may change from the amorphous state to the crystalline state (and vice versa) due to temperature changes of the phase change material. These temperature changes may be caused using different approaches. For example, a current may be driven through the phase change material (or a voltage may be applied across the phase change material). Alternatively, a current or a voltage may be fed to a resistive heater which is disposed adjacent to the phase change material. To determine the memory state of a resistivity changing memory element, a sensing current may be routed through the phase change material (or a sensing voltage may be applied across the phase change material), thereby sensing its resistivity which represents the memory state of the memory element.

FIG. 4 illustrates a cross-sectional view of an exemplary phase change memory element 400 (active-in-via type). The phase change memory element 400 includes a first electrode 402, a phase change material 404, a second electrode 406, and an insulating material 408. The phase change material 404 is laterally enclosed by the insulating material 408. To use the phase change memory element, a selection device (not shown), such as a transistor, a diode, or another active device, may be coupled to the first electrode 402 or to the second electrode 406 to control the application of a current or a voltage to the phase change material 404 via the first electrode 402 and/or the second electrode 406. To set the phase change material 404 to the crystalline state, a current pulse and/or voltage pulse may be applied to the phase change material 404, wherein the pulse parameters are chosen such that the phase change material 404 is heated above its crystallization temperature, generally keeping the temperature below the melting temperature of the phase change material 404. To set the phase change material 404 to the amorphous state, a current pulse and/or voltage pulse may be applied to the phase change material 404, wherein the pulse parameters are chosen such that the phase change material 404 is briefly heated above its melting temperature, and is quickly cooled.

The phase change material 404 may include a variety of materials. According to one embodiment, the phase change material 404 may include or consist of a chalcogenide alloy that includes one or more elements from group VI of the periodic table. According to another embodiment, the phase change material 404 may include or consist of a chalcogenide compound material, such as GeSbTe, SbTe, GeTe or AgInSbTe. According to a further embodiment, the phase change material 404 may include or consist of chalcogen free material, such as GeSb, GaSb, InSb, or GeGaInSb. According to still another embodiment, the phase change material 404 may include or consist of any suitable material including one or more of the elements Ge, Sb, Te, Ga, Bi, Pb, Sn, Si, P, O, As, In, Se, and S.

According to one embodiment, at least one of the first electrode 402 and the second electrode 406 may include or consist of Ti, V, Cr, Zr, Nb, Mo, Hf, Ta, W, or mixtures or alloys thereof. According to another embodiment, at least one of the first electrode 402 and the second electrode 406 may include or consist of Ti, V, Cr, Zr, Nb, Mo, Hf, Ta, W and one or more elements selected from the group consisting of B, C, N, 0, Al, Si, P, S, and/or mixtures and alloys thereof. Examples of such materials include TiCN, TiAlN, TiSiN, W—Al₂O₃ and Cr—Al₂O₃.

FIG. 5 illustrates a block diagram of a memory device 500 including a write pulse generator 502, a distribution circuit 504, phase change memory elements 506a, 506b, 506c, 506d (for example, phase change memory elements 400 as shown in FIG. 2), and a sense amplifier 508. According to one embodiment, the write pulse generator 502 generates current pulses or voltage pulses that are supplied to the phase change memory elements 506a, 506b, 506c, 506d via the distribution circuit 504, thereby programming the memory states of the phase change memory elements 506a, 506b, 506c, 506d. According to one embodiment, the distribution circuit 504 includes a plurality of transistors that supply direct current pulses or direct voltage pulses to the phase change memory elements 506a, 506b, 506c, 506d or to heaters being disposed adjacent to the phase change memory elements 506a, 506b, 506c, 506d.

As already indicated, the phase change material of the phase change memory elements 506a, 506b, 506c, 506d may be changed from the amorphous state to the crystalline state (or vice versa) under the influence of a temperature change. More generally, the phase change material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 508 is capable of determining the memory state of one of the phase change memory elements 506a, 506b, 506c, or 506d in dependence on the resistance of the phase change material.

To achieve high memory densities, the phase change memory elements 506a, 506b, 506c, 506d may be capable of storing multiple bits of data, i.e., the phase change material may be programmed to have more than two resistance values. For example, if a phase change memory element 506a, 506b, 506c, 506d is programmed to one of three possible resistance levels, 1.5 bits of data per memory element can be stored. If the phase change memory element is programmed to one of four possible resistance levels, two bits of data per memory element can be stored, and so on.

The embodiment shown in FIG. 5 may also be applied in a similar manner to other types of resistivity changing memory elements like programmable metallization elements (PMCs), magento-resistive memory elements (e.g., MRAMs), organic memory elements (e.g., ORAMs), or transition metal oxide memory elements (TMOs).

Another type of resistivity changing memory element may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory element may be formed in a manner similar to that described above with reference to phase change memory elements. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory element, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

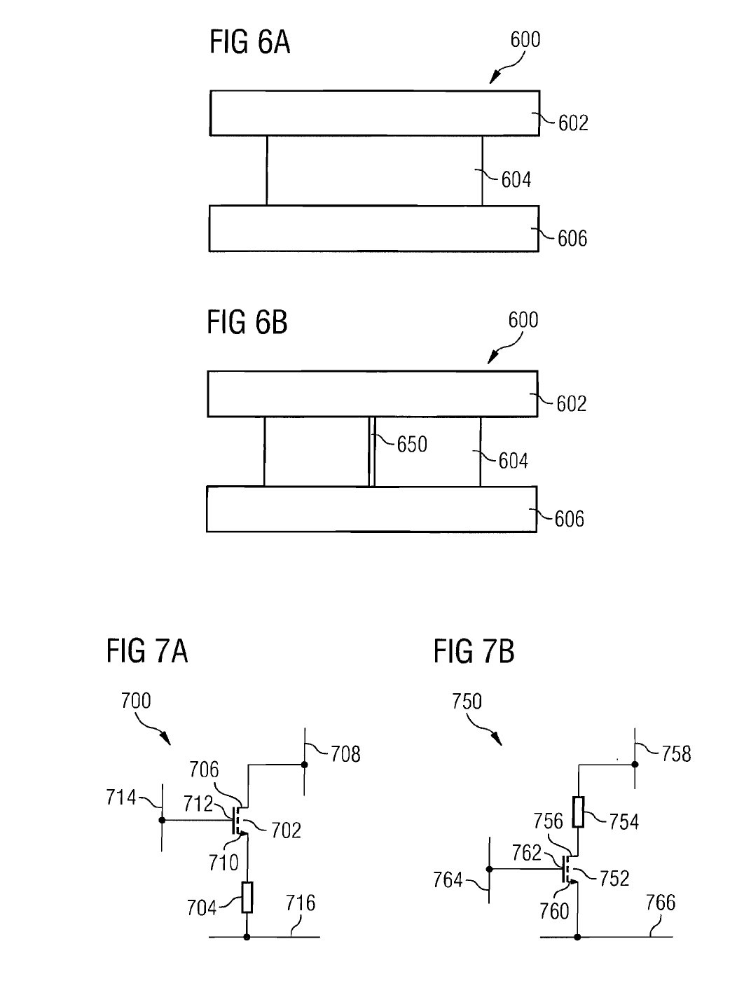

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 6A and 6B.

FIG. 6A shows a carbon memory element 600 that includes a top contact 602, a carbon storage layer 604 including an insulating amorphous carbon material rich in sp³-hybridized carbon atoms, and a bottom contact 606. As shown in FIG. 6B, by forcing a current (or voltage) through the carbon storage layer 604, an sp² filament 650 can be formed in the sp³-rich carbon storage layer 604, changing the resistivity of the memory element. Application of a current (or voltage) pulse with higher energy (or, in some embodiments, reversed polarity) may destroy the sp² filament 650, increasing the resistance of the carbon storage layer 604. As discussed above, these changes in the resistance of the carbon storage layer 604 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory element. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory elements, such as the phase change memory elements and carbon memory elements described above, may be used as part of a memory cell, along with a transistor, diode, or other active component for selecting the memory cell. FIG. 7A shows a schematic representation of such a memory cell that uses a resistivity changing memory element. The memory cell 700 includes a select transistor 702 and a resistivity changing memory element 704. The select transistor 702 includes a source 706 that is connected to a bit line 708, a drain 710 that is connected to the memory element 704, and a gate 712 that is connected to a word line 714. The resistivity changing memory element 704 also is connected to a common line 716, which may be connected to ground, or to other circuitry, such as circuitry (not shown) for determining the resistance of the memory cell 700, for use in reading. Alternatively, in some configurations, circuitry (not shown) for determining the state of the memory cell 700 during reading may be connected to the bit line 708. It should be noted that as used herein the terms connected and coupled are intended to include both direct and indirect connection and coupling, respectively.

To write to the memory cell 700, the word line 714 is used to select the memory cell 700, and a current (or voltage) pulse on the bit line 708 is applied to the resistivity changing memory element 704, changing the resistance of the resistivity changing memory element 704. Similarly, when reading the memory cell 700, the word line 714 is used to select the cell 700, and the bit line 708 is used to apply a reading voltage (or current) across the resistivity changing memory element 704 to measure the resistance of the resistivity changing memory element 704.

The memory cell 700 may be referred to as a 1T1J cell, because it uses one transistor, and one memory junction (the resistivity changing memory element 704). Typically, a memory device will include an array of many such cells. It will be understood that other configurations for a 1T1J memory cell, or configurations other than a 1T1J configuration may be used with a resistivity changing memory element. For example, in FIG. 7B, an alternative arrangement for a 1T1J memory cell 750 is shown, in which a select transistor 752 and a resistivity changing memory element 754 have been repositioned with respect to the configuration shown in FIG. 7A. In this alternative configuration, the resistivity changing memory element 754 is connected to a bit line 758, and to a source 756 of the select transistor 752. A drain 760 of the select transistor 752 is connected to a common line 766, which may be connected to ground, or to other circuitry (not shown), as discussed above. A gate 762 of the select transistor 752 is controlled by a word line 764.

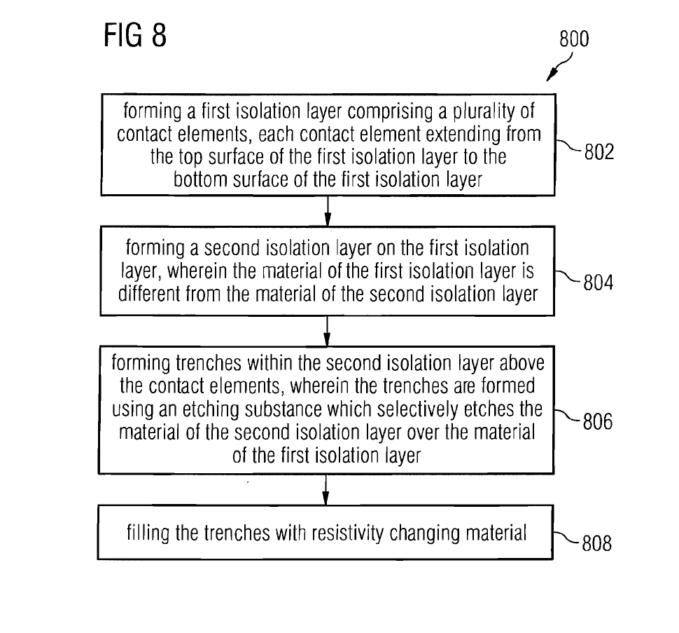

FIG. 8 shows a method of manufacturing an integrated circuit according to one embodiment of the present invention.

At 802, a first isolation layer comprising a plurality of contact elements is formed, each contact element extending from the top surface of the first isolation layer to the bottom surface of the first isolation layer. At 804, a second isolation layer is formed on the first isolation layer, wherein the material of the first isolation layer is different from the material of the second isolation layer. At 806, trenches are formed within the second isolation layer above the contact elements, wherein the trenches are formed using an etching substance which selectively etches the material of the second isolation layer over the material of the first isolation layer. At 808, the trenches are filled with resistivity changing material.

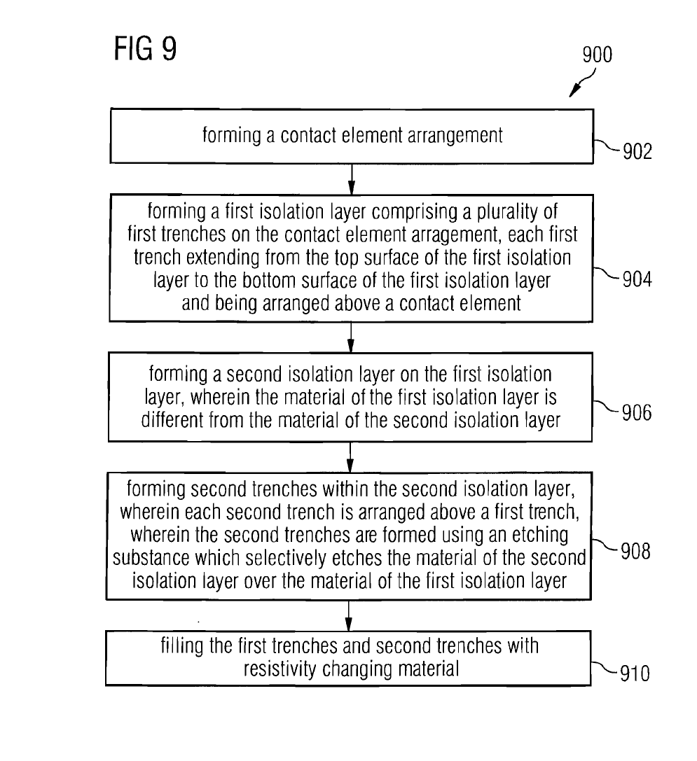

FIG. 9 shows a method of manufacturing an integrated circuit according to one embodiment of the present invention.

At 902, a contact element arrangement is formed. At 904, a first isolation layer comprising a plurality of first trenches is formed on the contact element arrangement, each first trench extending from the top surface of the first isolation layer to the bottom surface of the first isolation layer and being arranged above a contact element. At 906, a second isolation layer is formed on the first isolation layer, wherein the material of the first isolation layer is different from the material of the second isolation layer. At 908, second trenches are formed within the second isolation layer, wherein each second trench is arranged above a first trench, wherein the second trenches are formed using an etching substance which selectively etches the material of the second isolation layer over the material of the first isolation layer. At 910, the first trenches and second trenches are filled with resistivity changing material.

In the following description, making reference to FIGS. 11 to 14, a method of manufacturing an integrated circuit according to one embodiment of the present invention will be explained.

FIG. 11 shows a manufacturing stage A obtained after having formed a first isolation layer 1100 on a contact layer 1102. The first isolation layer 1100 includes a plurality of contact elements 1104, each contact element 1104 extending from the top surface 1106 of the first isolation layer 1100 to the bottom surface 1108 of the first isolation layer 1100. The contact layer 1102 includes a plurality of contacts 1110 which are isolated against each other and are connected to select devices like diodes, field effect transistors (FETs), bipolar transistors, etc., wherein each contact 1110 is arranged below a contact element 1104. The contact layer 1102 may, for example, consist of oxide, the contacts 1110 may, for example, include or consist of tungsten, the first isolation layer 1100 may, for example, include or consist of silicon nitride, and the contact elements 1104 may, for example, include or consist of TiN, TiSiN, TiAlN, TaAlN, TaSiN, WN, SiC, and the like. The contact elements 1104 may be formed within the first isolation layer 1100 by using a double patterning lithographic process, a combination of lithographic process and spacer process, a pore process, and the like, in order to form small trenches within the first isolation layer 1100. Then, the heater material can be deposited within the trenches. After this, a CMP (chemical mechanical polishing) process can be carried out until the top surface of the first isolation layer 1100 is exposed.

FIG. 12 shows a manufacturing stage B obtained after having formed a second isolation layer 1200 on the first isolation layer 1100, wherein the material of the first isolation layer 1100 is different from the material of the second isolation layer 1200. For example, the first isolation layer 1100 may be a nitride layer, and the second isolation 1200 layer may be an oxide layer; the first isolation layer may, for example, be a silicon nitride layer, and the second isolation layer may, for example, be a silicon oxide layer. Further, trenches 1202 (line pattern, interrupted line pattern or island pattern) have been formed within the second isolation layer 1200 using, for example, a lithographic process. The trenches 1202 are formed using an etching substance which selectively etches the material of the second isolation layer 1200 over the material of the first isolation layer 1100. Due to the selective etching process, an accurate etch stop on the top surface of the first isolation layer 1100 can be achieved. The accurate etch stop ensures reproducible electrical properties at the junction between the contact elements 1104 and the resistivity changing material 1300 to be filled into the trenches 1202, as shown in FIG. 13. Further, sidewall spacers 1204 have been formed within the trenches 1202 which cover the sidewalls of the trenches 1202, in order to encapsulate the resistivity changing material 1300 (here: phase change material). The material of the sidewall spacers 1204 may be the same material as that of the first isolation layer 1100, e.g., silicon nitride. The formation of the sidewall spacers 1204 may, for example, include a timed etchback of a spacer layer deposited in order to ensure a good control of the surface topography. Also, an oxide nitridation process may be used in order to manufacture the sidewall spacers 1204. If an oxide nitridation process is used to form the sidewall spacers 1204, no additional etchback process is needed to open the bottom contacts, i.e., in order to expose the top surface of the contact elements 1104. The thickness d1 of the sidewall spacers 1204 may, for example, range between about 1 nm to about 20 nm, about 3 nm to about 15 nm, or about 5 nm to about 10 nm.

FIG. 13 shows a manufacturing stage C obtained after having filled the trenches 1202 with resistivity changing material 1300, e.g., GST (GeSbTe) like GST:N, GST:SiO₂, GeSb:SiN, GeSb:SiO₂, etc., and after a planarization using a CMP process. Further, a top electrode layer 1302 and a bit line layer 1304 have been deposited. The material of the bit line layer 1304 may, for example, include or consist of W, TiN, AlCu, etc.

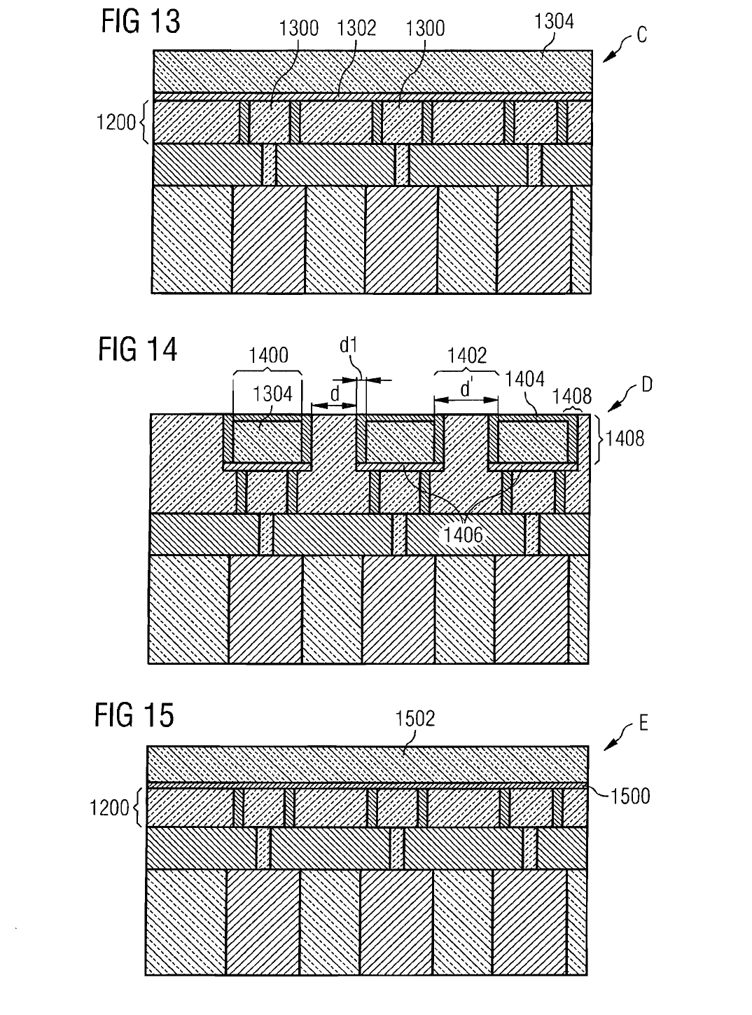

FIG. 14 shows a manufacturing stage D obtained after having patterned the bit line layer 1304 into bit lines 1400 by forming trenches 1402 within the bit line layer 1304 using, for example, a reactive ion etching process. The formation of the trenches 1402 within the bit line layer 1304 may be carried out using the top electrode layer 1302 as an etch stop layer. The top electrode layer 1302 may be patterned using the patterned bit line layer 1304 (i.e., the bit lines 1400) as a top electrode layer patterning mask. Further, an encapsulation layer 1404 has been deposited on the bit lines 1400. The material of the encapsulation layer 1404 may be the same material as that of the first isolation layer 1100 and of the sidewall spacers 1204. The patterning of the top electrode layer 1302 may be carried out after having formed the encapsulation layer 1404, wherein parts of the encapsulation layer 1404 covering the sidewalls of the bit lines 1400 (bit line sidewall spacers 1408) are used as a part of the top electrode layer patterning mask when patterning the top electrode layer 1302. As a consequence, depending on the thickness of the bit line sidewall spacers 1408, a distance d between two neighboring top electrodes 1406 is reduced by d1, wherein the d1 is the thickness of the bit line sidewall spacers 1408. Thus, the width of the trenches 1402 between the bit lines 1400 and the thickness d1 of the sidewall spacers covering the sidewalls of the bit lines 1400 can be chosen such that the distance d between two neighboring sidewall spacers (i.e., between two neighboring top electrodes 1406) is lower than about 1F, although the smallest feature size of the patterning masks (lithographic masks) does not have to be smaller than about 1F. The width of each trench between two neighboring bit lines d′ may, for example, be chosen to be about 1F. The same dimensions may also be chosen as far as the trenches 1202 and the sidewall spacers 1204 are concerned, i.e., the distance d shown in FIG. 12 may be lower than about 1F, whereas the distance d′ shown in FIG. 12 may be chosen to be 1F. The trenches 1402 may then be filled with isolation material, e.g., oxide or low k dielectric. One effect of reducing the distance d below 1F is that it is less likely that the resistivity changing material 1300 is accidentally exposed to the etching chemistry used for patterning of the top electrode layer 1302 in the case for some misalignment of the bit line trenches 1402 relative to the resistivity changing material trenches 1202. This prevents potentially negative effects (e.g., etching damage) on the resistivty changing material 1300 such as changes to its electrical or geometrical properties and thus improves the reproducibility of the integrated circuit.

FIG. 14 shows the case where the bit line material/top electrode material has been patterned. For particular bit line materials such as copper, an alternative approach to reach this stage may be more desirable, and the bit lines/top electrodes may be formed as explained below.

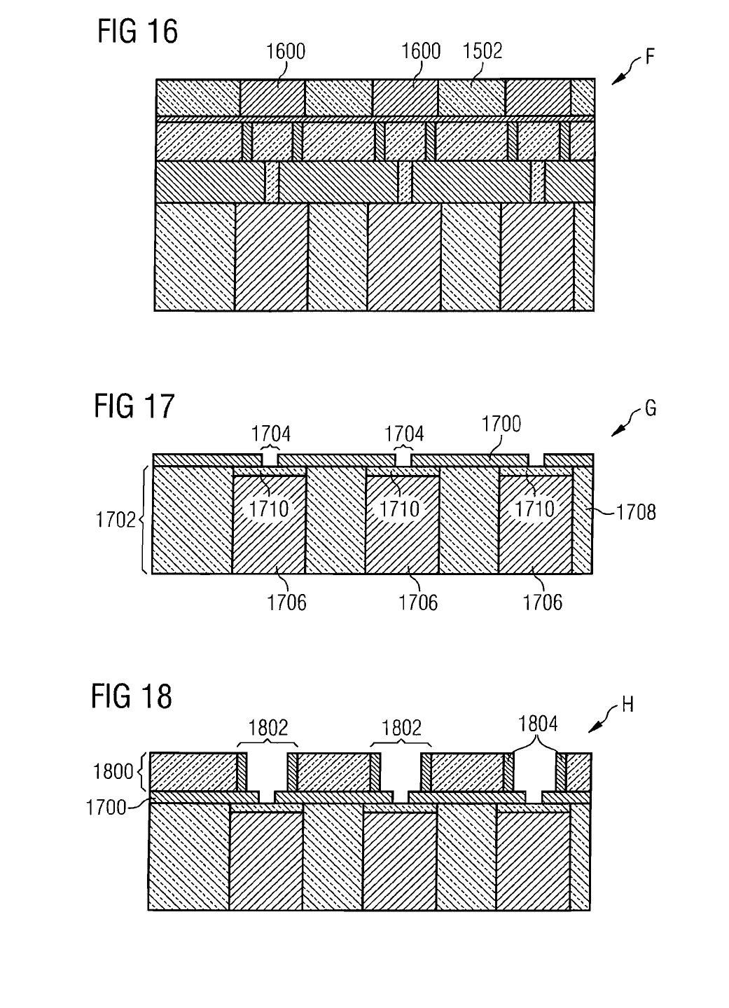

Starting from FIG. 12, the trenches 1202 are filled with resistivity changing material 1300. Then, an etch barrier layer 1500 is deposited on the structure thus obtained, wherein an isolation layer (e.g., oxide layer) 1502 is deposited on the etch barrier layer 1500, thereby obtaining manufacturing stage E shown in FIG. 15. The etch barrier layer 1500 may, for example, include or consist of SiN, nblok, SiC, SiCNH, etc., and may have a thickness between about 1 nm and about 50 nm, more preferred between about 5 nm and about 20 nm thickness. Then, trenches are formed above the trenches 1202 in the isolation layer 1502, wherein the trench formation process accurately stops on the etch barrier layer 1500 (patterning substance selectively etches material of the isolation layer 1502 over the material of the etch barrier layer 1500). Then, the etch barrier layer 1500 is opened using a different etching substance, thereby exposing the top surface of the resistivity changing material 1300. The trenches are then filled with conductive material 1600 (e.g., TaN and copper), thereby arriving at manufacturing stage F shown in FIG. 16.

In the following description, making reference to FIGS. 17 to 19, a method of manufacturing an integrated circuit according to one embodiment of the present invention will be explained.

FIG. 17 shows a manufacturing stage G obtained after having formed a first isolation layer 1700 on a contact layer 1702. The contact layer 1702 includes a plurality of contacts 1706 which are isolated against each other by isolation material 1708, for example, oxide. The top section of each contact 1706 includes a contact element 1710. The first isolation layer 1700 includes a plurality of first trenches 1704, each first trench 1704 extending from the top surface of the first isolation layer 1700 to the bottom surface of the first isolation layer 1700 and being arranged above a contact element 1710.

FIG. 18 shows a manufacturing stage H obtained after having formed a second isolation layer 1800 on the first isolation layer 1700, wherein the material of the first isolation layer 1700 is different from the material of the second isolation layer 1800. Further, second trenches 1802 have been formed within the second isolation layer 1800, wherein each second trench 1802 is arranged above a first trench 1704, wherein the second trenches 1802 are formed using an etching substance which selectively etches the material of the second isolation layer 1800 over the material of the first isolation layer 1700 (accurate etch stop on the second isolation layer 1800). The formation of the second trenches 1802 also removes material of the second isolation layer 1800 which has been filled into the first trenches 1704. Also, sidewall spacers 1804 have been formed covering the sidewalls of the second trenches 1800. The sidewall spacers 1804 may, for example, be formed by using a thin spacer layer deposition followed by a spacer etching process, or by using an oxide nitridation process (no potential disturb of the pore shape of the first isolation layer 1700). In the second case, also the top surface of the second isolation layer 1800 may be covered with sidewall spacer material.

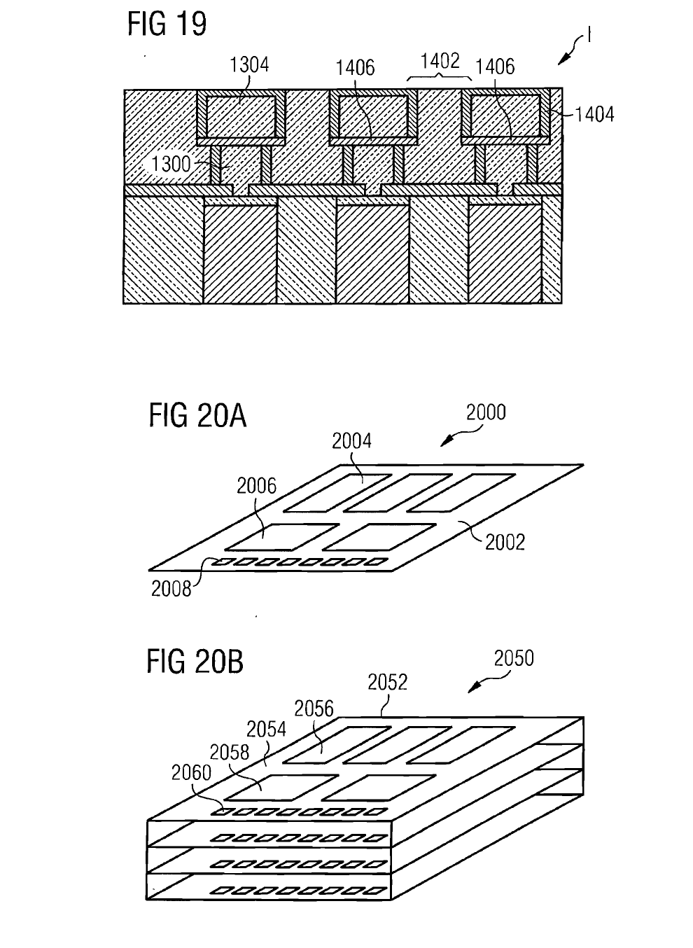

FIG. 19 shows a manufacturing stage I obtained after having filled the the first trenches 1704 and second trenches 1802 with resistivity changing material. Further, the steps as described in conjuntion with FIG. 13 and 14 have been carried out.

In this way, embodiments of the present invention provide etch damage free patterning of resistivity changing material (high reproducibility of electrical properties of resistivity changing material) and of top electrode material. Further, embodiments of the present invention make it possible to simultaneously encapsulate the resistivity changing material (e.g., by SiN material), thereby also improving the electrical properties of the storage element (e.g., no or less degradation of electrical properties during back end of line (BEOL) processes will occur). Further, embodiments of the present invention provide a self aligned patterning process of the top electrode layer. Further, embodiments of the present invention enable a low aspect ratio GST (GeSbTe) line fill.

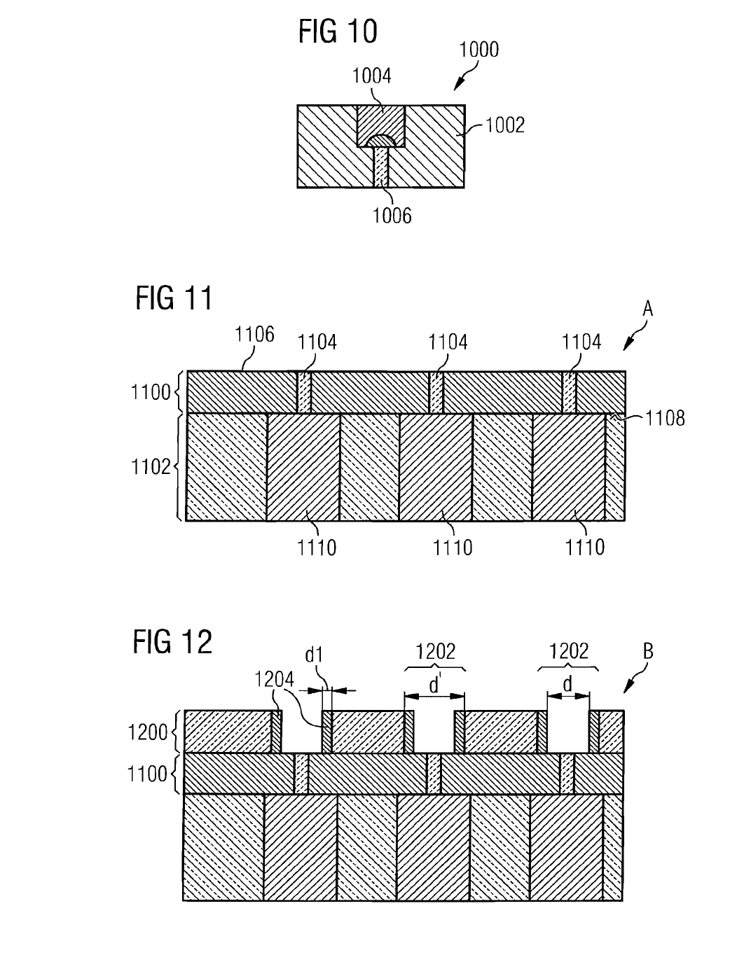

In contrast, FIG. 10 shows a phase change memory cell 1000 where problems may occur since only one isolation material 1002 encapsulates the resistivity changing material 1004 and the contact element 1006, which causes problems when forming the trench for depositing the resistivity changing material 1004 due to overetching issues (no reproducibility of geometry and electrical properties at the junction between the contact element 1006 and the resistivity changing material 1004).

As shown in FIGS. 20A and 20B, in some embodiments, integrated circuits such as those described herein may be used in modules. In FIG. 20A, a memory module 2000 is shown, on which one or more integrated circuits 2004 are arranged on a substrate 2002. The integrated circuits 2004 may include numerous memory cells. The memory module 2000 may also include one or more electronic devices 2006, which may include memory, processing circuitry, control circuitry, addressing circuitry, bus interconnection circuitry, or other circuitry or electronic devices that may be combined on a module with a memory device, such as the integrated circuit 2004. Additionally, the memory module 2000 includes multiple electrical connections 2008, which may be used to connect the memory module 2000 to other electronic components, including other modules.

As shown in FIG. 20B, in some embodiments, these modules may be stackable, to form a stack 2050. For example, a stackable memory module 2052 may contain one or more integrated circuits 2056, arranged on a stackable substrate 2054. The integrated circuits 2056 contain memory cells that employ memory elements. The stackable memory module 2052 may also include one or more electronic devices 2058, which may include memory, processing circuitry, control circuitry, addressing circuitry, bus interconnection circuitry, or other circuitry or electronic devices that may be combined on a module with a memory device, such as the integrated circuits 2056. Electrical connections 2060 are used to connect the stackable memory module 2052 with other modules in the stack 2050, or with other electronic devices. Other modules in the stack 2050 may include additional stackable memory modules, similar to the stackable memory module 2052 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing an integrated circuit comprising a plurality of memory cells, comprising:
forming a first isolation layer comprising a plurality of contact elements, each contact element extending from a top surface of the first isolation layer to a bottom surface of the first isolation layer;
forming a second isolation layer on the first isolation layer, wherein material of the first isolation layer is different from material of the second isolation layer;
forming trenches within the second isolation layer above the contact elements, wherein the trenches are formed using an etching substance which selectively etches the material of the second isolation layer over the material of the first isolation layer; and
filling the trenches with resistivity changing material.

2. The method according to claim 1, wherein the first isolation layer is a nitride layer, and wherein the second isolation layer is an oxide layer.

3. The method according to claim 1, wherein sidewall spacers are formed within the trenches before filling the trenches with the resistivity changing material.

4. The method according to claim 3, wherein the sidewall spacers comprise nitride.

5. The method according to claim 4, wherein the sidewall spacers are formed using a nitridation of sidewalls of the trenches.

6. The method according to claim 1, wherein the memory cells are phase change memory cells, and wherein the resistivity changing material is phase change material.

7. The method according to claim 1, wherein a top electrode layer is formed on the second isolation layer, and wherein a bit line layer is formed on the top electrode layer.

8. The method according to claim 7, wherein the bit line layer is patterned into bit lines by forming trenches within the bit line layer.

9. The method according to claim 8, wherein the formation of the trenches within the bit line layer is carried out using the top electrode layer as an etch stop layer.

10. The method according to claim 8, wherein the top electrode layer is patterned using the patterned bit line layer as a top electrode layer patterning mask.

11. The method according to claim 10, wherein an encapsulation layer is deposited on the bit lines.

12. The method according to claim 11, wherein the patterning of the top electrode layer is carried out after having formed the encapsulation layer, wherein the parts of the encapsulation layer covering sidewalls of the bit lines are used as a part of the top electrode layer patterning mask when patterning the top electrode layer.

13. The method according to claim 1,
wherein an etch stop layer is formed on the second isolation layer,
wherein a third isolation layer is formed on an etch stop layer,
wherein trenches are formed within the third isolation layer extending to a top surface of the etch stop layer using a first etching substance, each trench being formed above a trench filled with resistivity changing material;
opening parts of the etch stop layer positioned above the trenches filled with resistivity changing material using a second etching substance; and
filling the trenches thus obtained with bit line material.

14. The method according to claim 13, wherein the bit line material is copper.

15. A method of manufacturing an integrated circuit comprising a plurality of memory cells, comprising:
forming a contact element arrangement;
forming a first isolation layer comprising a plurality of first trenches on the contact element arrangement, each first trench extending from a top surface of the first isolation layer to a bottom surface of the first isolation layer and being arranged above a contact element;
forming a second isolation layer on the first isolation layer, wherein material of the first isolation layer is different from material of the second isolation layer;
forming second trenches within the second isolation layer, wherein each second trench is arranged above a first trench, wherein the second trenches are formed using an etching substance which selectively etches the material of the second isolation layer over the material of the first isolation layer; and
filling the first trenches and second trenches with resistivity changing material.

16. The method according to claim 15, wherein the second trenches are wider than the first trenches.

17. The method according to claim 15, wherein, before filling the first trenches and the second trenches with resistivity changing material, sidewalls of the second trenches are covered with a sidewall spacer.

18. The method according to claim 17, wherein the sidewall spacers are formed by a nitridation of the sidewalls of the second trenches.

19. A method of manufacturing an integrated circuit comprising a plurality of memory cells, comprising:
forming a first isolation layer comprising a plurality of resistivity changing memory elements, each resistivity changing memory element extending from a top surface of the first isolation layer into the first isolation layer;
forming a top electrode layer on the first isolation layer;
forming a pattern of bit lines on the top electrode layer; and
patterning the top electrode layer using the bit line pattern as a top electrode layer patterning mask, wherein the patterning of the top electrode layer is carried out after having formed an encapsulation layer on at least a part of the bit lines, wherein parts of the encapsulation layer covering sidewalls of the bit lines are used as a part of the top electrode layer patterning mask when patterning the top electrode layer.

20. An integrated circuit comprising a plurality of memory cells, each memory cell comprising:
a first isolation layer comprising a contact element which extends from a top surface of the first isolation layer to a bottom surface of the first isolation layer;
a second isolation layer provided on the first isolation layer, wherein the second isolation layer comprises a resistivity changing element which extends from a top surface of the second isolation layer to a bottom surface of the second isolation layer, and which is arranged above the contact element; and
wherein material of the first isolation layer is different from material of the second isolation layer.

21. The integrated circuit according to claim 20, wherein the first isolation layer is a nitride layer, and wherein the second isolation layer is an oxide layer.

22. An integrated circuit comprising a plurality of memory cells, each memory cell comprising:
a contact element;
a first isolation layer which is provided on the contact element and which comprises a first trench extending from a top surface of the first isolation layer to a bottom surface of the first isolation layer, wherein the first trench is arranged above the contact element;
a second isolation layer provided on the first isolation layer, wherein the second isolation layer comprises a second trench arranged above the first trench, wherein the second trench is wider than the first trench, and wherein the second trench extends from a top surface of the second isolation layer to a bottom surface of the second isolation layer;
wherein material of the first isolation layer is different from material of the second isolation layer, and
wherein the first trench and the second trench are filled with resistivity changing material.

23. The integrated circuit according to claim 22, wherein the first isolation layer is a nitride layer, and wherein the second isolation layer is an oxide layer.

24. The integrated circuit according to claim 23, wherein the first isolation layer is a silicon nitride layer, and wherein the second isolation layer is a silicon oxide layer.

25. The integrated circuit according to claim 22, wherein a width of the second trench is about 1F.
